(19) United States
(12) Patent Application Publication
(10) Pub. No.: US 2004/0132317 A1
(43) Pub. Date: Jul. 8, 2004

(54) Method for oxidation of silicon substrate

(76) Inventors: Per Morgen, Odense (DK); Kjeld Pedersen, Svenstrup (DK); Lars-Bo Tæker, Kobenhavn (DK); Thomas Jensen, Frorup (DK); Flemming K Dam, Odense (DK); Soren V Hoffmann, Tilst (DK)

Correspondence Address: NIXON PEABODY, LLP, 401 9TH STREET, NW, SUITE 900, WASINGTON, DC, 20004-2128, US

(21) Appl. No.: 10/471,202

(22) PCT Filed: Mar. 7, 2002
(86) PCT No.: PCT/DK02/00145

(30) Foreign Application Priority Data
Mar. 10, 2001 (DK) PA 2001 00408

(51) Int. Cl. H01L 21/31; H01L 21/469

(52) U.S. Cl. 438/770

(57) ABSTRACT

Method for oxidation of a silicon substrate under ultrahigh vacuum base conditions, wherein the substrate undergoes a number of oxidation cycles with exposure to oxygen and heat treatment for converting the adsorbed oxygen into silicon oxide.

### FIELD OF THE INVENTION

The present invention relates to a method for oxidising silicon under ultrahigh vacuum base conditions.

### BACKGROUND OF THE INVENTION

The semiconductor industry is continuously aiming at increasing the switching speed of transistors in order to increase the performance of computers. One of the most critical aspects for increased speed is the reduction of the width of the MOS (Metal-Oxide-Semiconductor) transistor gate and—correspondingly, following certain recognised scaling rules—the reduction of the thickness of the gate oxide. This oxide is the insulating layer between the semiconductor surface inversion layer through which current flows in parallel with the surface and the gate electrode of the transistor, which turns on and off the inversion condition, and thus the current flow. Typically, insulating silicon dioxide layers on silicon in transistors of year 2000 are between 20 and 100 molecular layers thick, and there is an assumed limit of thickness to withstand electron tunnelling of about 10 molecular layers of bulk silicon dioxide, which corresponds to a thickness of approximately 2.5 nm. A molecular layer is defined as the average thickness of a monolayer of bulk SiO₂, or exactly 0.24 nm for a density of 2264 kg/m³. Thus the controllable growth of such thin layers, meeting a number of demands on their bulk and interface properties, is vital for the industry.

Recently, researchers at Bell Labs have employed a method to produce a silicon dioxide layer with a thickness of five layers of silicon bound to oxygen, equivalent to 2.5 molecular layers with the definition discussed earlier. This was achieved by a rapid thermal oxidation of a clean silicon surface by exposure to 1000° C. for 10 seconds.

Thermal oxidation, including rapid thermal oxidation, by oxygen exposure at temperatures above 700° C. is the most well known method to achieve thick oxide layers, but has it limitations for the ultrathin oxide regime. Thus, according to work by A. Feltz et al. “High temperature scanning tunneling microscopy studies on the interaction of O₂ with Si(111)−7×7 surfaces” in Surf. Sci. 314, pp. 34 (1994), the method is very difficult to control, as it is a balance between surface etching and oxide growth. To achieve a certain thickness of an oxide layer in a controlled way requires a large number of trial and error experiments, to establish the “processing window”, which means the boundaries of the region in parameter space inside which the reaction leads to controlled and scaleable outcomes. The limiting factors are trench formation and island formation of the oxide, counteracting the formation of a smooth oxide—silicon interface, which is a requirement for the successful operation in devices.

Achieving ultrathin layers, that is to say from one layer up to 50 layers, in a controlled way demands a very thorough control of the actual process parameters such as dosing and heating phase, temperature ramping and cooling speed, making this method very hard to control and to scale.

Intel Corporation has recently produced even thinner silicon oxides than reported by Bell Labs. Their researchers have produced a “three-atom thick oxide layer” (probably equivalent to one averaged molecular layer according to the earlier definition) and included it in a working transistor. This obviously causes a renewed interest in finding the optimal methods for the production of the thinnest possible oxides on silicon.

In International patent application WO 00/59016, a method has been disclosed to achieve a thin and smooth silicon oxide layer with a thickness of less than 6 nm on a silicon substrate with increased tensile stress. This method includes a first step, where the silicon surface is exposed to oxygen at room temperature, after which the surface of the substrate is continuously exposed to oxygen at a higher temperature between 500° C. and 700° C.

As the oxidation happens continuously at the higher temperatures, the method is not suited for the controlled growth of layers only a few molecular layers thick.

The first step for the oxidation disclosed in the patent application WO 00/59016, where the surface of the substrate is exposed to oxygen at room temperature is reported to be “oxidation”, which could lead to an interpretation of this step to have produced a single layer of oxide. However, this is a misleading assumption, because formation of a stable oxide or oxide-like layer does not occur at room temperature. The binding of oxygen on the surface in this case is mainly a chemical adsorption, which is now well known to differ from a genuine oxide. A discussion of this can be found in P. Morgen et al., “From oxygen adsorption to oxidation of silicon” in Journal of Computational Materials, 2001 (accepted for publication).

The formation of thicker silicon oxide layers on silicon has been reported in a number of patents and articles. U.S. Pat. No. 5,817,581 discloses a method for oxidation of silicon implying wet and dry oxidation to achieve silicon oxide layers with thickness of several hundreds of nanometers. In the article by P.Soukiassian et al. “Catalytic Oxidation of Semiconductors by Alkali Metals” published in Physica Scripta, Vol. 35, 757-760 (1987), a method is reported for increasing the speed of oxidation of silicon by exposing the clean silicon surface to an alkali metal as a catalyst prior to oxidation at high temperature. The reported methods are not documented to cause a controllable formation of thin and smooth oxide layers with a control of the desired thickness.

From the article by P.Soukiassian et al. “Electronic properties of O₂ on Cs or Na overlayers adsorbed on Si(001)2×1 from room temperature to 650° C.” published in Physical Review B Vol. 35, No. 8, 4177-4179 (1987), and from P.Soukiassian et al. “SiO₂-Si interface formation by catalytic oxidation using alkali metals and removal of the catalyst species” published in J.Appl.Phys. 60 (12) 4039-4341 (1986), oxidation processes of Si have been reported, where silicon is exposed to an alkali metal and thereupon exposed to oxygen at room temperature. As a last step, the silicon substrate is heated to 650° C. in order to form a silicon oxide and for desorption of Cs. In the latter article, an oxide layer with a thickness of about 1 nm is achieved and the thickness is claimed to be dependent on the oxygen exposure and the alkali metal coverage.

Though an indication is given in these articles for how thick an oxide layer is achieved with these methods with a particular choice of parameters, it is not directly derivable how any other specific thickness of the oxide layer can be reached. The reason lies in the fact that no simple scaling can be demonstrated in these methods between the thickness of the oxide layer and the other parameters such as total oxygen exposure and total alkali metal coverage of the silicon surface.

As is apparent from the discussion above, a great number of experiments have been performed in order to find a method for production of oxide layers with any well-defined thickness, where the thickness can be varied in a controlled way from one layer to any higher, predetermined value. However, this problem has not yet been solved satisfactorily for any of the methods mentioned above.

### DESCRIPTION/SUMMARY OF THE INVENTION

It is the purpose of this invention to provide a method for the controlled and scaleable oxidation of silicon where the thickness of the oxide layer can attain any chosen value between one monolayer and some tens of nanometers and with high precision.

This purpose is achieved by a method for oxidation of a silicon substrate under ultrahigh vacuum base conditions, wherein said substrate undergoes at least one oxidation cycle and heat treatment for transforming the adsorbed oxygen into silicon oxide, wherein said oxidation cycle is repeated for a predetermined number of times.

According to the invention, a silicon substrate is exposed to oxygen gas under ultrahigh vacuum conditions but with a raised partial pressure in the chamber of typically 10⁻⁵ Pa of pure oxygen. During this step, oxygen is adsorbed on the surface, where the adsorption rate of the oxygen is independent of the temperature if it is below 150° C. It is an obvious convenience to be able to expose the surface of the substrate to oxygen near room temperature. Thus at room temperature or likewise in a temperature regime between −100° C. and 150° C., the total amount of adsorbed oxygen is only very weakly dependent on the oxygen exposure conditions for total exposure values above 100 Langmuir (L), where 1 L=10⁻⁶ Torr·s=1.33·10⁻⁴ (N/m²)·s. A higher oxygen exposure does not result in a substantially higher amount of adsorbed oxygen on the surface even for exposures of thousands of L. Therefore, it is possible to achieve a chemical adsorption of oxygen on the surface of the substrate with a narrowly defined amount of adsorbed oxygen atoms filling all available surface sites. In this way, the total amount of oxygen retained on the substrate after evacuation of the chamber, does not depend critically on temperature or oxygen pressure and is, therefore, easily reproducible.

After such an exposure to oxygen, leaving a well defined amount of oxygen atoms bound in the surface, the silicon substrate is treated by heating under vacuum conditions of a pressure less than 10⁻⁶ Pa, preferably less than 10⁻⁷ Pa, to a temperature of between 500° and 815° C. depending on the desired conditions and explained in more detail below. An annealing time of between 30 and 60 seconds at this temperature is typically sufficient. At these temperatures and times, all the adsorbed oxygen atoms transform into silicon oxide, SiO₂, covering only part of the surface, as no further oxygen is supplied in the heating process. In order to increase the amount of oxide on the substrate, the process is repeated.

In a certain embodiment of the invent ion, a thin but fully covering oxide layer is achieved by exposing the clean silicon surface of a substrate to oxygen in a number of oxidation cycles, where each cycle is followed by heating to a temperature of 550° C. An annealing time of between half a minute and one minute is typically sufficient. At these temperatures and times, the initially adsorbed oxygen atoms, which are bound in the surface of the substrate, are in the first annealing step transformed into silicon oxide clusters covering only part of the surface, as no further oxygen is supplied in the heating process. In order to increase the oxide island coverage, the process is repeated three to four times, which is as many times as additional oxygen can be adsorbed at the surface and converted into oxide upon heating. Hereafter, the system has become inert to further adsorption of oxygen, and a stable oxide layer, which is the thinnest possible oxide layer that can exist on silicon, has been created.

The mono-molecular layer of silicon oxide created with this method has been thoroughly studied and characterised to ensure that its physical and chemical properties are satisfactory for deployment in actual electronic components, in view of the fact that it must differ from a truly bulk-like system.

A further embodiment of the invention can be used for the growth of thicker oxide layers. In this case, the oxidation cycle comprises deposit of an alkali metal, preferably Cs, for example by evaporation from a SAES dispenser, on the substrate prior to exposure to oxygen. As is well known, a thin layer of Cs, preferably a monolayer, on the silicon surface enhances the uptake of oxygen on this surface. Therefore, as a second step, the substrate with the Cs surface is exposed to oxygen for saturated oxygen adsorption.

After exposure to oxygen, the adsorbed dose of oxygen is converted into silicon oxide by a heat treatment of the sample, at above 550° C. but below 700° C., for a period of a half up to one minute, in an oxygen free high vacuum environment. During this heat treatment, all traces of Cs disappear from the surface.

To overcome the barrier for further adsorption of oxygen on the now already oxidised surface, a layer of Cs atoms is deposited on top of the oxide using a similar dosing time and conditions as for covering the clean silicon surface.

Oxidation cycles of Cs deposition and oxygen exposure followed by heating is repeated for a number of times. During heating after each oxidation, Cs is released from the substrate. In this procedure, the oxide layer grows approximately linearly in thickness for the first five cycles, after which the growth slows down, and ultimately a thickness of approximately 3 layers of oxide can be reached, with the upper part bulk like.

No difference of the finally achieved oxide layer thickness was observed, whether Cs in the first cycle was deposited on a clean silicon surface or Cs was deposited on a silicon surface that had first been exposed to oxygen prior to Cs deposition.

In a still further embodiment of the invention, still thicker silicon oxide layers can be achieved with no saturation of the growth process and still with maximum control as will be described in the following. To accommodate more oxygen as adsorbed species prior to oxidation by heating, several oxidation cycles with alternating Cs- and oxygen deposit at or near room temperature may be used to produce a growing film of a mixed species of these two elements. After a number of such completed cycles, heating to between 500° C. and 815° C., typically for periods of a half to one minute, serves to create a layer of silicon dioxide on top of silicon and to desorb Cs. The resulting silicon oxide thickness is linearly depending on the number of oxidation cycles.

As an alternative to Cs, also Na, K, and Rb may be used to enhance oxygen uptake on a silicon substrate.

### SHORT DESCRIPTION OF THE DRAWINGS

The invention will be explained more in detail in the following with reference to the drawings, where

FIG. 1 shows experimental spectroscopic results in the form of integrated O 1s XPS signals during the oxidation process of Si(111) and Si(0001) according to the First Recipe,

FIG. 2 shows determined oxide layer thickness and chemical composition, for the oxidation process of Si(111) and Si(001) according to the First Recipe,

FIG. 3 shows determined oxide layer thickness and chemical composition, when the oxidation method involves Cs deposition, for Si(111) and Si(0001) according to the Second Recipe,

FIG. 4 shows the O 1s XPS spectrum for the oxidation method involving Cs deposition on the Si(111) substrate according to the Second Recipe,

FIG. 5 shows Si 2p XPS spectra describing the quantity of silicon oxide on the sample after various exposure cycles according to the Third Recipe,

FIG. 6 shows a diagram of the thickness of the Sio₂ film as a function of number of exposure cycles according to the Third Recipe,

FIG. 7 shows Cs 3d XPS spectra describing the quantity of Cs left in the oxide after processing by using 15 cycles of exposure according to the Third Recipe and after heating up to different temperatures for a minute,

FIG. 8 shows the Cs 3d XPS signal intensity (area) for extended heating times in minutes at 580° C. of a sample created with 15 cycles of exposure according to the Third Recipe, and

FIG. 9 shows photoemission spectra, recorded with synchrotron radiation of 130 eV photon energy, of the clean surface and the surface covered by an oxide with a thickness of 6.4 nm according to the Third Recipe.

### DETAILED DESCRIPTION OF THE INVENTION/PREFERRED EMBODIMENT

In the following, a number of experiments will be described, which have been performed in order to demonstrate the growth of oxide layers on silicon in a controlled way with a specified thickness.

For preparation of the substrate, a standard procedure was used as a cleaning process of polished single crystal silicon wafers, which in the experiments were of n-type with a resistivity of 5 ohm-cm and oriented in (111) or (001) directions. However, crystals with other resistivities and orientations can be used as well.

The substrates were flash heated to 1000° C. a number of times, after which the surfaces were clean and reconstructed in the known structures as could be monitored with LEED (Low Energy Electron Diffraction), Photoemission, and Optical Second Harmonic Generation Spectroscopy.

### Creation of One Monolayer of Oxide (or Oxide-like Substance) (First Recipe)

In order to produce a silicon oxide layer on the silicon substrate, where the oxide layer has a thickness nominally equivalent to 1 molecular layer, a method is applied, which in short notation can be illustrated as: Si+O+heat+O+heat.

Having the cleaned silicon substrate at room temperature in an evacuated chamber at a pressure around 10⁻⁶ Pa, oxygen gas was supplied to the chamber corresponding to exposure of the clean surface to 100 L oxygen. During this step, oxygen is adsorbed on the silicon surface but does not form a“real” oxide layer. Instead, it forms a saturated chemically adsorbed layer of atomic oxygen imbedded in the surface.

Subsequently, the chamber was evacuated for oxygen and the surface, with the adsorbed oxygen, was annealed at a temperature of 550° C. for 60 seconds. After this, the cycle of oxygen exposure followed by heating was repeated three times, at 550° C. for 60 seconds, and up to 700° C. in the last step.

After each step, spectroscopic measurements were performed with synchrotron radiation and the resulting photoemission spectra were used to characterise the system, which is described in more detail in P. Morgen et al. “Formation of the thinnest possible oxides on silicon”, submitted to Phys. Rev. Letters in March, 2001.

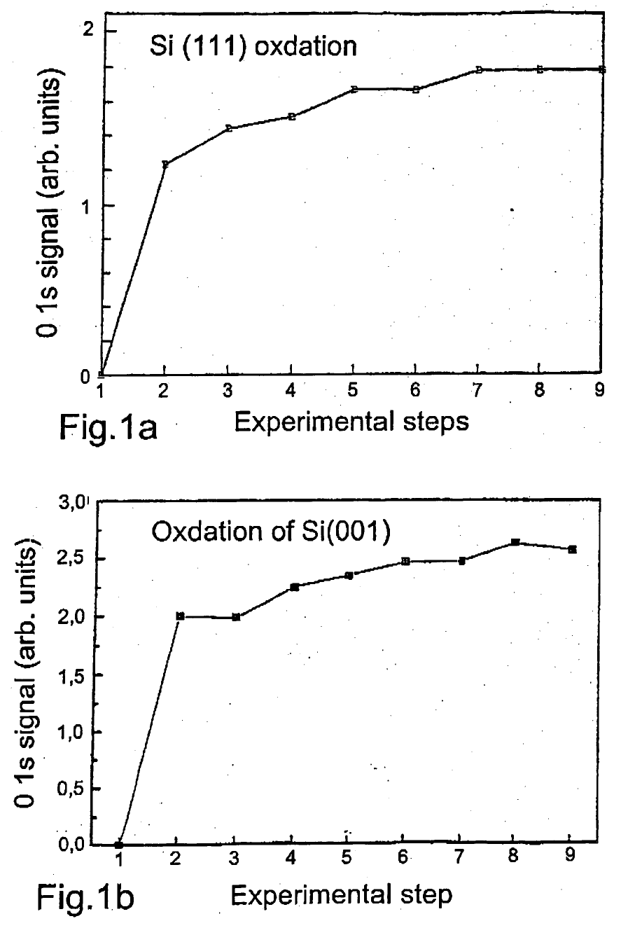

From these measurements, the intensity (peak area) of the spectroscopic signal from the 1s electronic level in oxygen, which is shown in FIG. 1, reflects the amount of oxygen bound on and in the silicon substrate. Step 1 represents the cleaned silicon surface. Steps 2, 4, and 6 represent identical steps with exposure to oxygen, while steps 3, 5, 7 represent heating at 550° C. To check whether a higher oxygen uptake would be possible with a higher dose and a higher temperature, the oxygen dose was chosen to be higher (300 L) in step 8, and the temperature was chosen higher, namely 700° C., in step 9. However, the uptake of oxygen was not increased despite the higher oxygen dose and higher temperature.

From the curve in FIG. 1a, for Si(111), it is apparent, that the oxygen uptake almost saturates after three cycles (step 7). The saturation after a few cycles is in contrast to oxidation as typically performed at high temperatures, where additional oxygen is normally available and therefore leads to the continuous formation of more oxide. The formation of a precise thickness of oxide at these high temperatures, however, is difficult to control and reproduce, involving a complicated temperature and oxygen pressure sequence.

For oxygen uptake on Si(001), a curve corresponding to Si(111) is also shown in FIG. 1b.

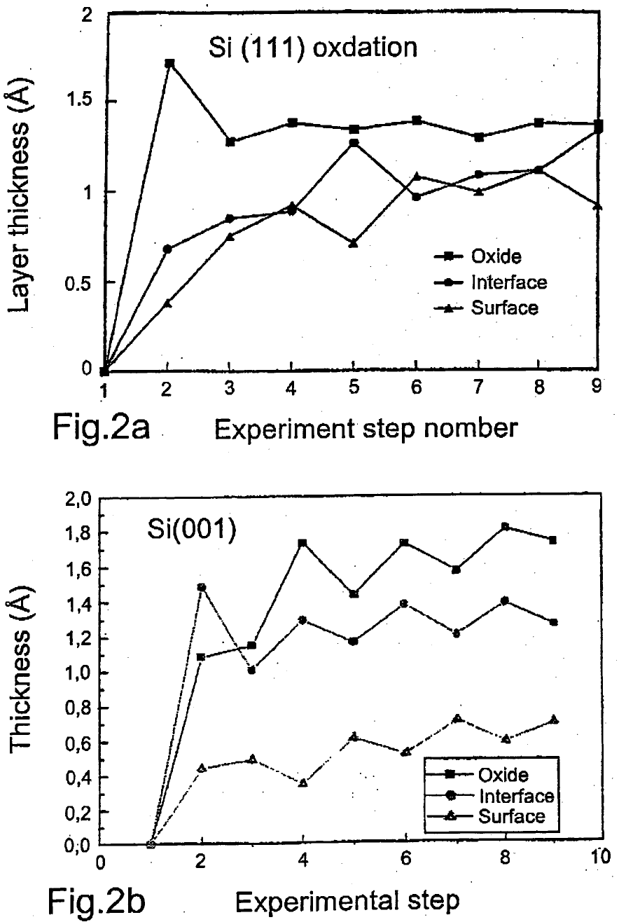

Studying the attenuation of signals from deeper atomic layers, and the variable chemical composition, the thickness of the silicon oxide layer and the chemical composition in the oxide layer can be determined, which is shown in FIG. 2a for Si(111) and in FIG. 2b for Si(001). The oxide layer thickness and chemical composition may be read from the figure to represent less than a full layer of stoichiometric silicon dioxide (but with a total thickness slightly above a molecular layer as defined above to have a thickness of 0.24 nm).

The large up-and-down variations in these curves are due to the large relative changes between mere adsorption, heating to stabilise and contract the oxide and additional adsorption, and testify to the large difference between the adsorbed and oxidised state of oxygen in the surfaces. The different curves in FIG. 2 have been obtained by differentiation between measured signals using the assumption that 3 oxygen atoms in the surface surround silicon atoms, that 1 or 2 oxygen atoms in the interface surround them, and that in a truly bulk-like oxide layer they should be surrounded by 4 oxygen atoms.

For the Si(111) surface, the largest fraction of silicon atoms are found in the interface region, while for Si(001), the structures contain more bulk like oxide for equivalent processing steps.

As can be seen in FIG. 1, the initial steps for both surfaces show that after initial adsorption and saturation of the surface with oxygen, the first couple of heating cycles make room for more oxygen to be adsorbed on the surface. This is due to the clustering of oxide. These clusters finally coalesce to cover the surface uniformly.

The physical meaning of a layer, like the ones produced here, and the thickness values may be less obvious than for correspondingly thicker layers. However, a test experiment with a metal (Ag) layer deposited on top proved the oxide layer to be continuous and isolating without holes and that tunnelling did not discharge it. It is therefore directly applicable in electronic devices.

A general aim is to keep the interface region as thin and smooth as possible in order to create as few defects as possible and, consequently—in an actual MOS transistor—produce the lowest scattering of inversion layer electrons or holes.

This process creates the thinnest possible usable oxide coverage on a silicon surface, which is around 0.3 nm thickness as also can be read from the figure by addition of the three curves. It has the further advantage of having a high degree of latitude, where the so-called latitude is a well known term meaning independence of the final result from variations of the parameters. This has been demonstrated by varying the temperature during oxygen exposure between −100° C. and 150° C. and the oxygen dose between 100 L and 500 L with an annealing temperature of between 500° C. and 700° C.

In a very detailed study, it was found that the interface structure and the distribution of variably oxidised silicon atoms through the thin oxide phase were clearly different for two silicon surface orientations, the Si(111) and Si(001) faces. In both cases the structure was also different from those of thicker oxides, but with dielectric properties proper for the actual use in devices.

### Creation of an Oxide Layer of up to 0.7 nm (Second Recipe)

In order to produce a thicker silicon oxide layer on the silicon substrate, with more bulk-like properties than for the first recipe, a second method is applied, which is short notation can be illustrated as: Si+Cs+O+heat+Cs+O+heat . . . or, alternatively, Si+O+Cs+O+heat+Cs+O+heat. . . .

In this case, Cs was deposited on a clean silicon surface from a SAES™ alkali dispenser source. However, the man skilled in the art may use a different dispenser source if appropriate. The amount of Cs covering silicon was chosen to be approximately a monolayer. On the clean silicon surface, a single layer of Cs may be deposited with ease, but not any more layers above that, as further deposition reevaporates Cs due to its high vapour pressure.

In an alternative experiment, the clean silicon surface was first exposed to 100 L oxygen before exposure to Cs. No significant difference was experienced between the two experiments regarding the final oxide layer thickness. However, a difference was experienced in the kinetics and the path of Cs adsorption on the substrate.

After exposure to 100 L oxygen, the sample was annealed between 550° C. and 700° C., typically for around 60 seconds, whereby Cs desorbs and oxide forms.

In subsequent oxidation cycles, a new monolayer of Cs was deposited on the substrate surface prior to exposure to 100 L oxygen. The sample was then heated but to a higher temperature after each oxidation cycle. As more oxide was added, a gradual increase in the annealing temperature and times was administered, tested against the decomposition of the oxide, and resulting in a “better” oxide structure, with fewer defects. In the last cycle a temperature of 700° C. was used.

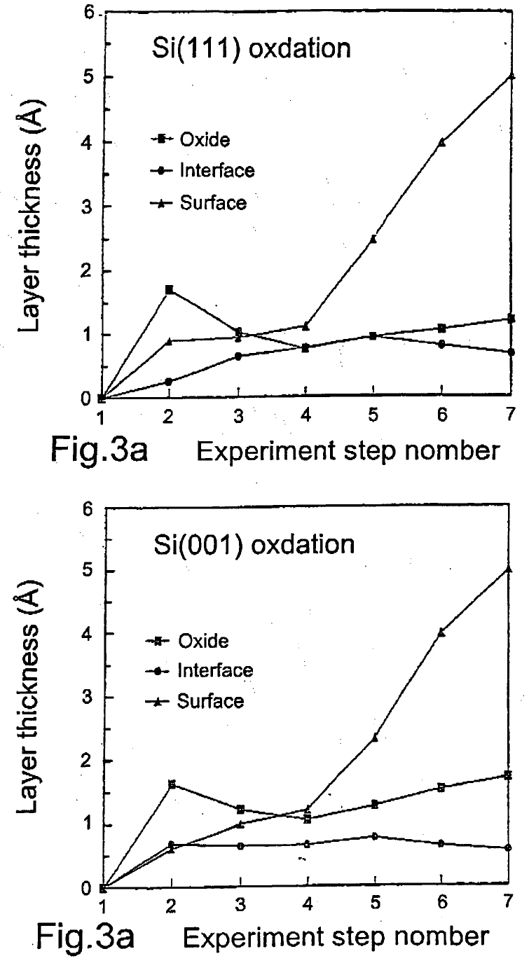

From spectroscopic measurements, described in more detail in P.Morgen et al.“New methods for the growth of thin oxides on the Si(111) and Si(001) surfaces” submitted to Phys. Rev.B, March 2001, the resulting thickness and chemical compositions have been analysed as shown in FIG. 3. As shown in FIG. 1, step 1 represents the clean silicon surface; step 2 represents oxygen deposition; step 3 represents heating; step 4, 5, 6 and 7 represent a full oxidation cycle with Cs deposition and oxygen exposure followed by annealing. In this case, it was chosen to oxidise the substrate without prior Cs deposition. However, Cs deposition prior to the first oxygen exposure would lead to an equivalent final oxide layer.

From FIG. 3, it is apparent that the oxygen uptake happens in very regular ways for both surfaces, but that the chemical compositions are different. For both surfaces some genuine oxide (silicon bound to four oxygen atoms) is found, and this layer grows linearly with number of cycles. The rather drastic oscillations of the intensities reflect the difference in density and structure of the system after oxygen adsorption and annealing stabilising the oxide.

However, the total amount of oxygen bound in the system tends towards saturation after a few more cycles, yielding a total maximum obtainable oxide thickness of around 0.75 nm for Si(111) and Si(001), or about three molecular layers.

It is an advantage, if the oxygen dose on the Cs surface is slightly higher than the dose used to saturate the clean silicon surface, i.e. larger than 100L, but no strict control is required. For the best repeatability, the doses of Cs and oxygen in all subsequent steps should be set slightly larger than the doses used in the first steps.

### Creation of an Oxide Layer with Larger Thickness (Third Recipe)

In order to produce a silicon oxide layer on the silicon substrate, where the oxide layer has any desired thickness between 0.4 nm and about 30 nm, with a desired repeatability, a method is applied, which in short notation can be illustrated as Si+O+Cs+O+Cs+O . . . +heat or,alternatively,Si+Cs+O+Cs+O . . . +heat.

Though this method works well for thicknesses larger than 10 nm, different and eventually more preferable methods exists for the production of layers with a thickness larger than 10 nm.

According to this embodiment of the invention, a clean silicon surface is exposed to Cs followed by exposure oxygen between 100 L and 300 L, preferably 100 L, at temperatures between −100° C. and 150° C., but preferably at room temperature. This oxidation cycle is repeated a number of times resulting in a growing film of Cs and oxygen.

In a final step, the substrate is heated to a temperature in the range from 550° C. to 815° C. for desorption of Cs and for oxidation of the silicon with the adsorbed oxygen. The temperature is chosen high enough for the Cs to desorb, but not higher than 815° C., where oxygen, which in this case is not yet bound as an oxide, may be released from the surface of the substrate. A temperature slightly below 815° C., for example 800° C. is advisable.

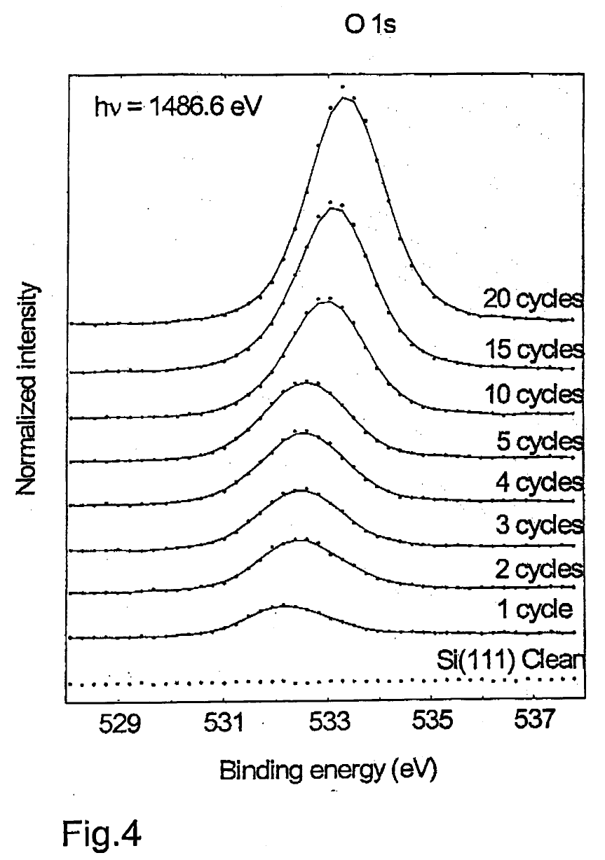

FIG. 4 illustrates spectroscopic signals from the Is electronic level of oxygen as obtained by XPS (X-ray Photoelectron Spectroscopy) from the Si(111) substrate after heating of the substrate with the final Cs/O film. The number of cycles used for deposition of the Cs/O film before heating is indicated for each spectrum. As the amount of oxygen increases, it is seen that the peak increases correspondingly in height. Furthermore, the peak moves towards higher binding energies. This fact is well known from the literature as indicating that the system gradually becomes more stable and well co-ordinated.

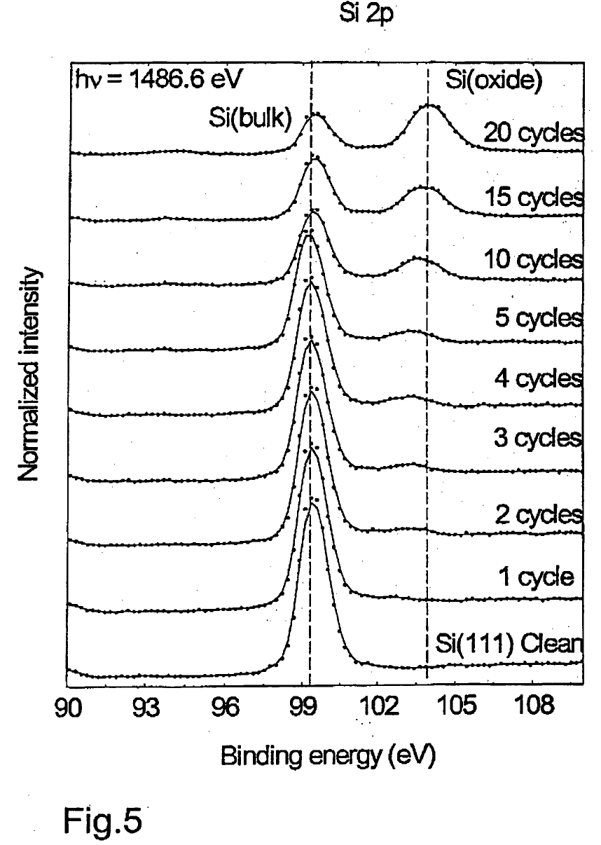

FIG. 5 illustrates the Si 2p XPS spectra for all oxidations in the series. The signal contains contributions from bulk silicon as well as from the oxide. It is seen that, as the number of cycles is increased, the Si 2p bulk signal is attenuated while the signal representing oxidised silicon increases. The actual difference in peak position of approximately 4.5 eV between bulk and oxidised silicon atom 2p levels also indicates that the result is a homogenous, high quality oxide. The Si 2p spectra distinguishing the oxidised and un-oxidised proportions of silicon atoms, as seen with photoemission, are used to calculate the oxide thickness dₒₓ. Taking the lowering of the intensity of the peak representing the un-oxidized Si atoms into account, the oxide thickness can be expressed as:

dₒₓ=sin(θ)λₒₓ 1n(I₀/I),

where θ is the angle between the surface plane and the analyser entrance (here θ=90°), λₒₓ is the electron mean free path in the oxide film (here: 3.5 nm), and I₀ and I are un-oxidized Si 2p peak intensities (peak areas) of the clean surface and the surface covered by the oxide film, respectively.

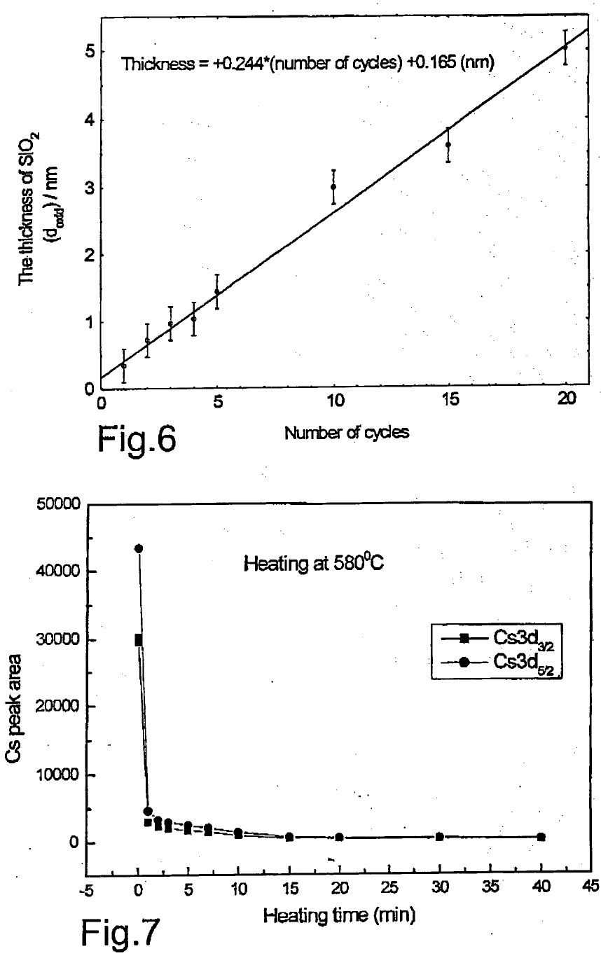

For each measured point of the series, the thickness has been calculated by the equation given above. These thickness values are displayed in FIG. 6 as a function of number of oxidation cycles including Cs deposition before final heat treatment. This figure illustrates that it is possible according to the invention to produce oxides with a any thickness within the range of 0.4 nm and 5 nm, where the thickness depends linearly on the number of exposed cycles. The error bars indicate the total estimated systematic and statistical uncertainties, which can be kept constant for the present experimental conditions. Further experiments have shown that the method according to the invention is scaleable up to thicknesses of more than 10 nm oxide.

FIG. 7 shows the Cs 3d XPS signal intensity (area) for extended heating times in minutes at 580° C. of a sample created with 15 oxidation cycles. It is obvious from the figure that Cs desorbs also at relatively low annealing temperature like in this case at 580° C.

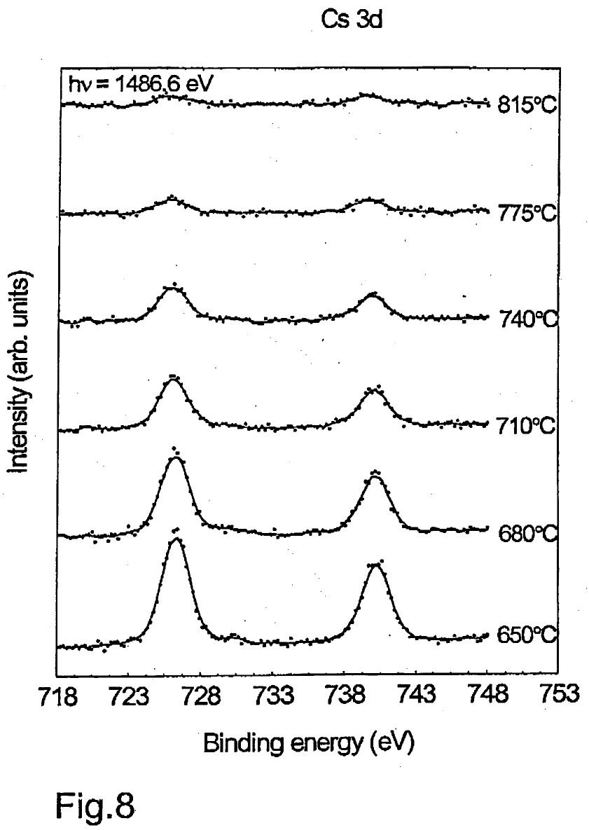

To illustrates the desorption efficiency of caesium at different temperatures, Cs 3d XPS spectra have been recorded after heating for 1 minute at various temperatures in the range 600-815° C. These spectra are shown in FIG. 8, where the different heating temperatures are indicated for the different spectra. Caesium is desorbed to a higher degree as the annealing temperature is increased, which is reflected by the decreasing peak signals. It is seen that Cs has almost disappeared at 815° C.

Other experiments have shown caesium to disappear completely for longer or for repeated heating cycles at 815° C. Thus, to ensure a complete Cs desorption, eventually several heating cycles or a longer annealing time may be employed.

The experiment thus demonstrates that it is possible to produce oxide of the desired thickness and with an extremely high degree of repeatability and at the same time remove the alkali used to enhance the adsorption.

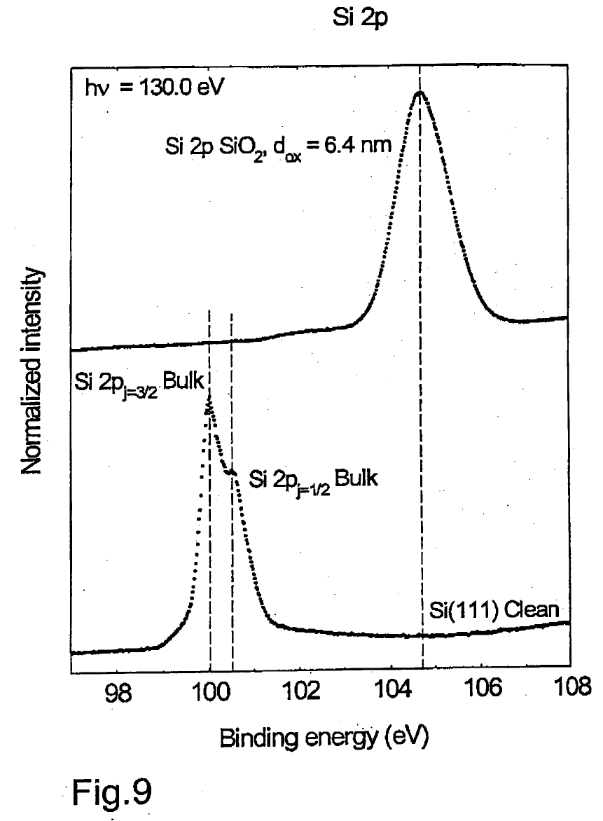

FIG. 9 shows the surface sensitive photoelectron Si 2p spectra of the clean silicon crystal (lower curve), and an oxide made by the method described above and with a determined thickness of 6.4 nm (upper curve). As expected, it indicates the presence of a homogeneous oxide within the probing depth, since there is only a weak indication of intermediary oxide present compared to the dominant signal from fully oxidised silicon, SiO₂. Also, the relative chemical shift of approximately 4.5 eV of the peak corresponding to the silicon oxide as compared to the peak corresponding to bulk silicon, indicates that the oxide is of high quality, i.e. is homogenous and without islands or holes.

The method used to measure substrate temperatures above 450° C. in all the processes makes use of a calibrated spot photometer. This allows the temperature to be measured without contacting the substrate. The photometer was adjusted for silicon emissivity and for absorption in the windows of the ultrahigh vacuum chamber. Lower substrate temperatures were measured with a thermocouple in contact with the substrate holder.

1. Method for oxidation of a silicon substrate under ultrahigh vacuum base conditions, wherein said substrate undergoes at least one oxidation cycle and heat treatment for transforming the adsorbed oxygen into silicon oxide, characterised in that said oxidation cycle is repeated for a predetermined number of times.

2. Method according to claim 1, wherein said oxidation cycle comprises exposure to oxygen of between 100 L and 1000 L, preferably 100 L.

3. Method according to claim 1 or 2, wherein the substrate is heated after each oxidation cycle to a temperature of between 500° C. and 650° C., preferably 550° C.

4. Method according to claim 1 or 2, wherein said oxidation cycle prior to exposure to oxygen comprises exposure to at least one from the group of alkali metals consisting of Na, K, Cs and Rb.

5. Method according to claim 4, wherein said oxidation cycle comprises deposit of Cs with a surface coverage of between 0.4 atomic layers and 1 atomic layers, preferably a full layer, and wherein the substrate is heated after each oxidation to a temperature of between 550° C. and 815° C., preferably 700° C.

6. Method according to claim 4, wherein said oxidation cycle comprises deposit of Cs with a surface coverage of between 0.4 atomic layers and 1 atomic layer, preferably a monolayer, and wherein the substrate is heated after the predetermined number of oxidation cycles to a temperature of between 550° C. and 815° C., preferably 800° C.

7. Method according to claim 6, wherein said method comprises an additional annealing process to assure complete extraction of Cs from the oxide and creation of a stable and continuous oxide, wherein said additional annealing process includes at least one cycle of a duration of one minute at a temperature of 815° C.

8. Method according to any single one of the previous claims, wherein said heating is performed under vacuum conditions with a pressure less than 10⁻⁶ Pa, but preferably less than 10⁻⁷ Pa.
